(19) United States
(12) Patent Application Publication
(10) Pub. No.: US 2020/0043563 A1
(43) Pub. Date: Feb. 6, 2020

(54) One-Time Programmable (OTP) Lock Circuit

(71) Applicant: Microsoft Technology Licensing, LLC, Redmond, WA (US)

(72) Inventors: Martin F. GALINSKI, Santa Clara, CA (US); Andrei SUHENCO, Mountain View, CA (US); Michael T. SNELLA, Mountain View, CA (US)

(73) Assignee: Microsoft Technology Licensing, LLC, Redmond, WA (US)

(21) Appl. No.: 16/054,866

(22) Filed: Aug. 3, 2018

(51) Int. Cl. G11C 17/18; G11C 11/412; G11C 29/02

(52) U.S. Cl. CPC G11C 17/18; G11C 29/027; G11C 11/412

(57) ABSTRACT

The disclosure relates an enhanced security feature that protects the data stored in an integrated circuit inside a device from reprogramming by software. A lock circuit, which resides outside the integrated circuit, provides a one-time programmable (OTP) solution that can be implemented using a fuse, a transistor, and a resistor, which are standard, off-the-shelf, discrete, board-level parts. After memory inside the integrated circuit has been programmed, the transistor can be turned on to blow the fuse, which permanently sets an external pin of the integrated circuit to a logical low voltage. The memory inside the integrated circuit is protected from further programming so long as the external pin has a logical low voltage. Since the fuse has been physically blown, the memory inside the integrated circuit is protected from undesirable changes by malicious software.

### BRIEF DESCRIPTION OF THE DRAWINGS

The accompanying drawings illustrate implementations of the concepts conveyed in this disclosure. Features of the illustrated implementations can be more readily understood by reference to the following description in conjunction with the accompanying drawings. Like reference numbers in the various drawings are used where feasible to indicate like elements. In some cases, parentheticals are utilized after a reference number to distinguish like elements. Use of the reference number without the associated parenthetical is generic to the element. The accompanying drawings are not necessarily drawn to scale.

FIG. 1A shows a perspective view a device that includes a one-time programmable (OTP) system in accordance with some implementations of the present concepts.

FIG. 1B shows a perspective view of a board that includes an OTP system in accordance with some implementations of the present concepts.

FIG. 2 shows a block diagram of an OTP system including a circuit diagram of a lock circuit in accordance with some implementations of the present concepts.

FIG. 3 shows a graph of an input voltage over time that may be used with some implementations of the present concepts.

FIG. 4 shows a block diagram of an OTP system including a circuit diagram of a lock circuit in a different state compared to that in FIG. 2, in accordance with some implementations of the present concepts.

FIG. 5 shows a flow chart of an OTP write method that can implement some of the present concepts.

FIG. 6 shows a flow chart of an OTP lock method that can implement some of the present concepts.

### DETAILED DESCRIPTION

The present concepts relate to enhancing security of devices that include integrated circuits (ICs). Security enhancements may be achieved with a lock circuit that resides outside ICs. The lock circuit can be added to any device containing an IC and can provide a hardware solution that locks the IC from unwanted changes. The lock circuit may be deactivated while the IC is being programmed. When it is desirable to lock the IC after programming is complete, the lock circuit may be activated to permanently prevent undesirable changes to the IC by malicious software.

A lock circuit according to the present concepts may be used to provide an OTP option for hardware locking a data bit. Therefore, the present concepts have a wide range of applications where it is desirable to deter hackers and malicious software from changing data stored in ICs. The present OTP solutions have several advantages over traditional security solutions that will become apparent with the detailed descriptions below. As a brief overview, the present OTP solutions are simpler and far less expensive than conventional solutions that reside inside silicon chips. Furthermore, the present OTP solutions are versatile as they can be used with existing silicon chips without spending millions of dollars and months or years to redesign and manufacture silicon chips with a lock solution. Moreover, the present OTP solutions require less power and use simpler interfaces compared to conventional solutions. These and other benefits of the present concepts will be explained below in relevant context.

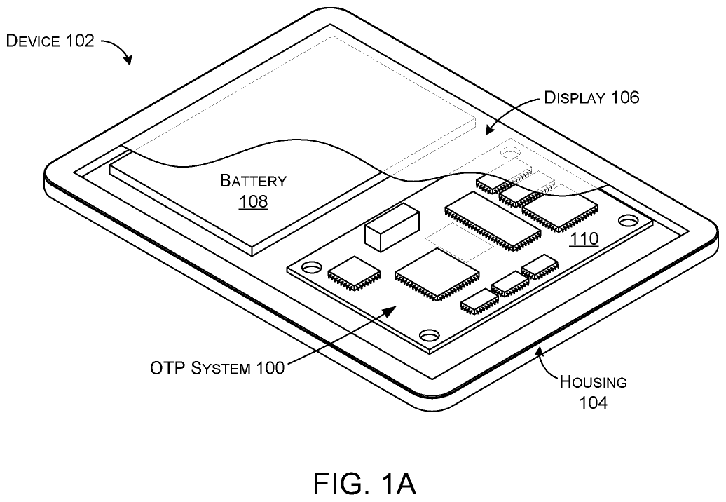

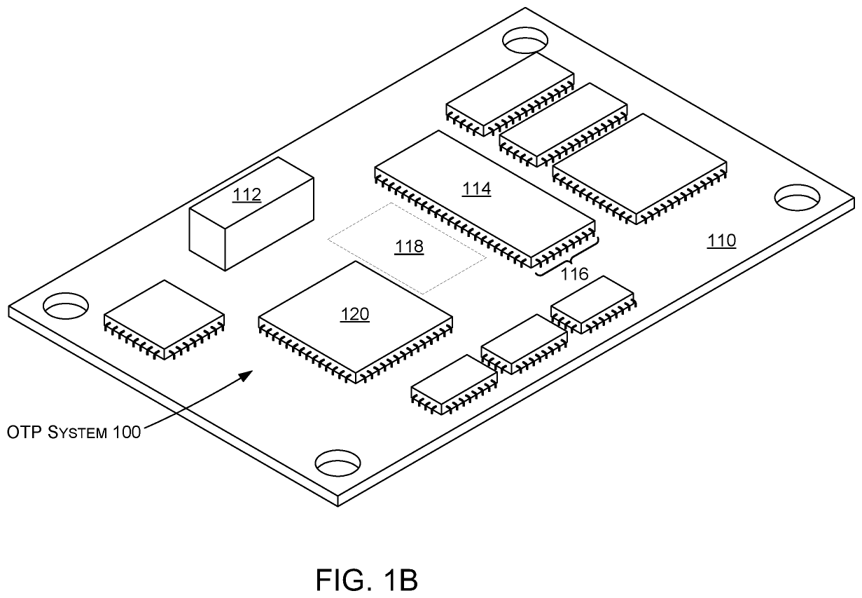

FIG. 1A shows a perspective view of an OTP system 100 in accordance with some implementations of the present concepts. In particular, FIG. 1A shows a partial cut-away view of an example device 102 that includes OTP system 100. Device 102 may be any electronic device or computing device. A computing device can mean any type of device that has processing capability and/or storage capability. Examples of computing devices include personal computers, servers, desktop computers, laptop computers, cell phones, smart phones, tablets, personal digital assistants, pad-type computers, mobile computers, appliances, smart devices, IoT devices, televisions, printers, drones, speakers, routers, etc., and any of a myriad of ever-evolving or yet-to-be-developed types of computing devices.

In the case illustrated in FIG. 1A, device 102 is depicted as a tablet. Device 102 can include a housing 104 for enclosing various components of device 102. In this example, device 102 may include a display 106, a battery 108, and a board 110. Device 102 can also include many other components that are not necessarily illustrated or discussed herein, including, for example, buttons, electrical ports, speakers, microphones, etc. Board 110 may include OTP system 100 according to the present concepts. Board 110 and various components thereon, including OTP system 100, will be discussed more in detail in reference to FIG. 1B and subsequent figures.

FIG. 1B shows a perspective view of board 110 that includes OTP system 100 in accordance with some implementations of the present concepts. Whereas FIG. 1A showed board 110 inside device 102, FIG. 1B shows board 110 outside device 102 (not shown in FIG. 1B). Board 110 can be an electronic circuit board, such as a printed circuit board (PCB) or a breadboard. Board 110 can include a plurality of electronic components that are electrically connected via conductive tracks or traces (not shown). Board 110 may include a power supply 112 for powering and supplying preset supply voltages to power rails (not shown) on board 110. Power supply 112 may be, for example, an on-board power management controller that draws power from battery 108 (shown in FIG. 1A) or any other sources of power and provides predetermined power levels to various components on board 110.

Board 110 may also include one or more ICs. For example, board 110 may include an IC 114. IC 114 can have external connectors, such as a plurality of external pins 116, that allow IC 114 to be connected to other components. The purposes of external pins 116 depend on the design and functionality of IC 114. Some of external pins 116 may have power-related functions, for example, by being connected to power supply 112 or to ground. Some of external pins 116 may be used as input pins to control or communicate with IC 114. For example, input pins may be used to configure or write data to IC 114. Some of external pins 116 may be used as outputs to export data from IC 114 and/or to communicate with other components.

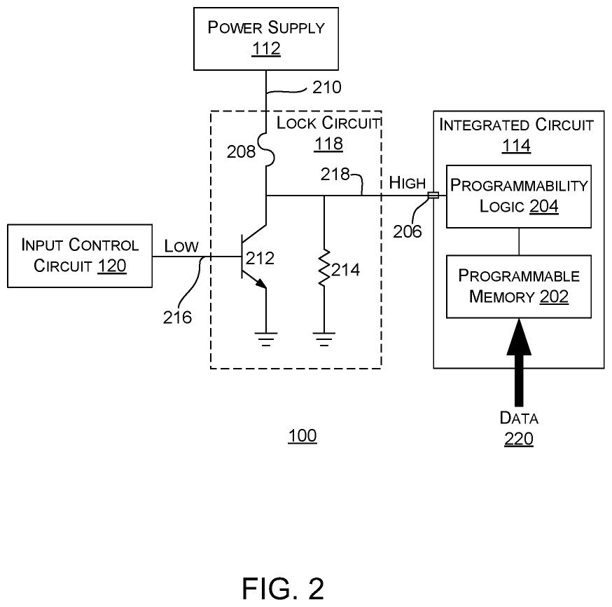

Board 110 may also include a lock circuit 118. Lock circuit 118, according to the present concepts, can provide a hardware OTP option for permanently locking the programmability of IC 114. Traditional hardware lock implementations are manufactured inside silicon chips, such as IC 114. As such, they are complex in design and expensive to make. Conventional in-silicon solutions are often large and do not provide the ability to control just one bit. The OTP solutions according to the present concepts involve lock circuit 118 that is outside silicon chips. Lock circuit 118 may be made up of discrete board-level components that are soldered or mounted directly on board 110 rather than being on a silicon substrate of an IC. Accordingly, the present concepts provide the ability to permanently set a “1” or a “0” value on a single data bit using small inexpensive components as a hardware lock of the data bit, thereby preventing malicious software from changing the data bit value. An example composition of lock circuit 118 will be explained in reference to FIGS. 2-4 below. Furthermore, because lock circuit 118 is not integrated into an IC, the present OTP solution is flexible in that it can provide a secure hardware lock option to existing ICs without expensive and protracted redesigning and manufacturing of ICs. That is, lock circuit 118 may be easily used to enhance security of an existing chip and avoid a substantial chip redesign that could cost millions of dollars and/or take months to execute.

Board 110 may include an activation component, such as an input control circuit 120, for activating and deactivating lock circuit 118. Input control circuit 120 may be an integrated silicon chip (as illustrated) or it may be made up of discrete components. Input control circuit 120 can activate lock circuit 118 to enable the hardware lock of IC 114, or input control circuit 120 can deactivate lock circuit 118 to permit programming of IC 114. Example structural compositions and functional operations of OTP system 100 will be explained below in references to additional figures.

FIG. 2 shows a block diagram of OTP system 100 including a circuit diagram of lock circuit 118 in accordance with some implementations of the present concepts. FIG. 2 depicts power supply 112, IC 114, lock circuit 118, and input control circuit 120 from FIG. 1B as blocks. As shown in FIG. 2, IC 114 may include programmable memory 202 that contains a plurality of memory cells for storing data. Any type of data may be written to memory 202, for example, via one or more external pins 116 (shown in FIG. 1). Memory 202 may store, for example, identifier information or software code, including firmware.

IC 114 may also include programmability logic 204 that controls a programmability state of memory 202, i.e., whether all or part of memory 202 may be programmable. In one implementation of the present concepts, programmability logic 204 may be configured such that when a logical high voltage level is detected on one of external pins 116, for instance, an external pin 206, data may be written to memory 202, whereas when a logical low voltage level is detected on external pin 206, data may not be written to memory 202. Alternatively, IC 114 may be designed in the opposite configuration, i.e., memory 202 is programmable when external pin 206 has a logical low voltage, and the memory 202 is write-protected when external pin 206 has a logical high voltage. Accordingly, IC 114 may be designed such that memory 202 is either programmable or write-protected depending on the voltage level detected on a particular one of the external connectors, i.e., external pin 206. Programmability logic 204 may be implemented via hardware or software, or a combination. External pin 206 of IC 114 may be configured as a standard general-purpose input/output (GPIO) interface pin. A simple and generic interface suffices for the present concepts, whereas conventional in-silicon implementations often involve complex and specialized serial or parallel interfaces.

Example structural components inside lock circuit 118 will now be discussed. In some implementations of the present concepts, lock circuit 118 may include a protection component, such as a fuse 208. A fuse is typically used as a safety component that protects against overcurrent in a circuit. A fuse is a sacrificial component that starts out closed, i.e., conducting electricity via a metal wire or strip with very little resistance, but when too much current flows through it, the metal wire or strip breaks and the fuse opens (or blows), thereby breaking the circuit. Once a fuse blows, it must by physically repaired or replaced in order to complete the circuit again. Fuse 208 may be any type of fuse, such as a low-voltage fuse, a cartridge type fuse, a link type fuse, a blade type fuse, a surface mount fuse, an axial fuse, etc.

Fuse 208 can have specific characteristics, such as a rated current (or a threshold current) and a rated voltage. Fuse 208 may conduct current flow levels below its threshold current but blow open when a current level flowing through it exceeds the threshold current. The characteristics of fuse 208 may also include blow time or time delay, which describes the amount of time the current flow level must exceed the threshold current to blow open fuse 208. Fuse 208 may be a standard, off-the-shelf, discrete, board-level component that is soldered directly on board 110 rather than residing inside an integrated silicon chip such as IC 114. Fuse 208 may have any package size, such as, for example, 0402 or 0201.

Fuse 208 is shown in a closed state in FIG. 2. Fuse 208 may have two terminals. Fuse 208 may be connected to power supply 112. For example, the first of the two terminals of fuse 208 may be coupled to a power rail line 210 powered by power supply 112.

Lock circuit 118 may also include a switch component, such as a transistor 212. Transistor 212 can act as a switch and/or an amplifier. Transistor 212 may be any type of transistor, such as a bipolar junction transistor (BJT) or a field effect transistor (FET) including a junction field effect transistor (JFET), a metal oxide semiconductor field effect transistor (MOSFET), and an insulated gate field effect transistor (IGFET); an n-channel type or a p-channel type; an NPN type or a PNP type; a depletion type or an enhancement type; a voltage-controlled type or a current-controlled type; etc. Transistor 212 can have three terminals labeled (1) gate or base, (2) drain or collector, and (3) source or emitter. The labeling convention depends on the type of transistor, but the labels can also be loosely used interchangeably among different types of transistors.

In operation, a voltage between the gate and the source of transistor 212 (i.e., a gate-source voltage or just a gate voltage) can control a current between the drain and the source of transistor 212. Transistor 212 can have specific characteristics, such as a turn-on voltage (or a threshold voltage). When zero voltage or a low voltage that is below the turn-on voltage level is applied to the gate, transistor 212 will be in an off state and current will not flow between the drain and the source, whereas when a high voltage that is at or above the turn-on voltage level is applied to the gate, transistor 212 will be in an on state and current will flow between the drain and the source. The on state of a transistor is also referred to as the active state or the conducting state, and the off state of a transistor is also referred to as the inactive state or the non-conducting state. Any voltage that turns on a transistor may be termed a turn-on voltage, and any voltage that turns off a transistor may be termed a turn-off voltage. Transistor 212 may be a standard, off-the-shelf, discrete, board-level component that is soldered directly on board 110 rather than residing inside an integrated silicon chip such as IC 114. Transistor 212 may have any package size, such as, for example, 0603.

Transistor 212 may be coupled with fuse 208. For instance, the second terminal of fuse 208 may be connected to the drain terminal of transistor 212. The combination of a fuse and a FET transistor is commonly called a FET fuse. The source terminal of transistor 212 may be connected to ground.

Lock circuit 118 may also include a resistor 214. A resistor is a passive component that implements electrical resistance, and therefore reduces current flow and adjusts voltage levels. Resistor 214 may be any type of resistor, such as a carbon composition resistor, a carbon film resistor, a metal film resistor, a cermet resistor, a surface mount resistor, etc. Resistor 214 can have specific characteristics, such as its resistance. Resistor 214 may be a standard, off-the-shelf, discrete, board-level component that is soldered directly on board 110 rather than residing inside an integrated silicon chip such as IC 114. Resistor 214 may have any package size, such as, for example, 0201.

Resistor 214 may have two terminals. The first terminal of resistor 214 may be connected to the second terminal of fuse 208 and the drain terminal of transistor 212. The second terminal of resistor 214 may be connected to ground. The second terminal of resistor 214 and the source terminal of transistor 212 may be connected to a common ground.

As described above, lock circuit 118, according to some implementations of the present concepts, may include three common, readily available, off-the-shelf parts. As such, lock circuit 118 is far simpler and cheaper to build than conventional solutions that are implemented inside silicon chips. Lock circuit 118 may have a small form factor that takes up only a few square millimeters (mm²) of area on board 110.

Additionally, lock circuit 118 may include an input line 216 that is connected to input control circuit 120 and the gate terminal of transistor 212. For example, input control circuit 120 may include a standard GPIO interface pin that is coupled to input line 216, such that input control circuit 120 can apply certain voltages to the gate of transistor 212. Unlike conventional hardware lock solutions, OTP system 100 may be implemented using simple and universal interfaces.

Lock circuit 118 may also include an output line 218 that is connected to the second terminal of fuse 208, the drain terminal of transistor 212, and the first terminal of resistor 214. Output line 218 of lock circuit 118 may also be connected to IC 114 via its external pin 206.

Now the operation of OTP system 100, consistent with some implementations of the present concepts, will be explained. Input control circuit 120 may send a low or zero voltage level signal on input line 216 of lock circuit 118. Since input line 216 is coupled to the gate terminal of transistor 212, input control circuit 120 can keep transistor 212 in the off state by maintaining a voltage level that is below the turn-on voltage level of transistor 212.

While transistor 212 is in the off state, current from power supply 112 will flow through power rail line 210, through fuse 208 in the closed state, and then to output line 218. In one implementation, power rail line 210 may have a supply voltage level of 1.8 V. Other supply voltage levels (such as 3.3 V) are possible in different implementations and still achieve the same function and effect consistent with the present concepts. The voltages required to implement the present concepts are sub-lithium-ion battery voltages, which are lower than conventional silicon implementations that often require high voltages greater than a single-cell Li-ion battery voltage. Therefore, the present concepts consume less power than conventional implementations.

In the case where 1.8 V is provided at power rail line 210, approximately 1.8 V (or slightly lower) may be expected at output line 218 (i.e., the voltage across resistor 214), because fuse 208 in the closed state has very little resistance (for example, 3 ohms (Ω)) and transistor 212 in the off state has very high resistance. In one implementation, resistor 214 can have, for example, 100Ω or 10 kΩ resistance.

The high voltage (e.g., 1.8 V) at output line 218 of lock circuit 118 passes to external pin 206 of IC 114 and may be detected by programmability logic 204 inside IC 114. In response to detecting the high voltage on external pin 206, programmability logic 204 may set memory 202 in a programmable state. Programmability logic 204 therefore may permit data 220 to be written to memory 202 so long as a logical high voltage is detected on external pin 206. Accordingly, if input control circuit 120 maintains a low voltage at input line 216 of lock circuit 118, data writes to (i.e., programming of) memory 202 of IC 114 is permitted.

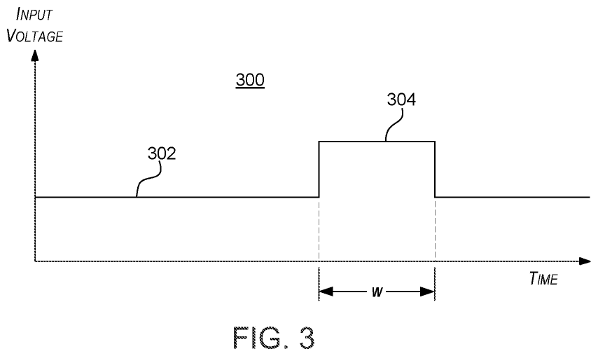

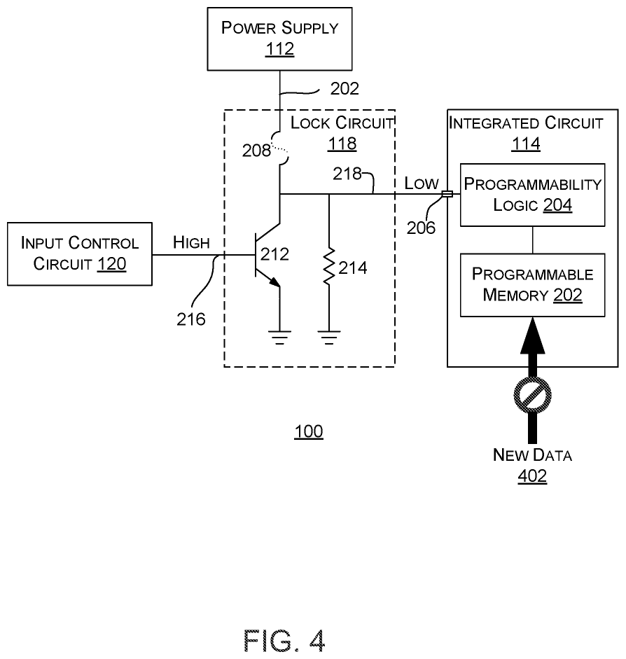

FIG. 3 shows a graph 300 of an input voltage over time that may be used with some implementations of the present concepts. Graph 300 in FIG. 3 will be referenced while continuing the description of FIG. 2 and also while describing FIG. 4 later. Graph 300 illustrates example voltage levels that may be output by input control circuit 120 (shown in FIG. 2) via a GPIO pin to input line 216 of lock circuit 118. Input control circuit 120 may send a low voltage level 302 (as shown before the pulse in FIG. 3) to input line 216 of lock circuit 118. Low voltage level 302 may be 0 V or may have a small positive voltage that is less than the turn-on voltage level of transistor 212. Low voltage level 302, as explained above, may keep transistor 212 in the off state, keep fuse 208 in the closed state, and cause a logical high voltage to be output on output line 218 of lock circuit 118 to external pin 206 of IC 114, such that memory 202 is programmable.

Next, memory 202 of IC 114 may be locked from data writes by input control circuit 120 sending a pulse of a high voltage level 304 (shown in FIG. 3) to input line 216 of lock circuit 118. High voltage level 304 may be, for example, 3.7 V, or any voltage level sufficient to turn on transistor 212, depending on the characteristics of transistor 212. The effects of high voltage level 304 will be explained in reference to FIG. 4.

FIG. 4 shows a block diagram of OTP system 100 including a circuit diagram of lock circuit 118 in a different state than that in FIG. 2, in accordance with some implementations of the present concepts. Input control circuit 120 may send a signal having high voltage level 304 (for example, the pulse shown in FIG. 3) on input line 216 of lock circuit 118. Since input line 216 is coupled to the gate terminal of transistor 212, input control circuit 120 can turn on transistor 212 by raising the voltage level at the gate of transistor 212 to be at or above the turn-on voltage level of transistor 212.

When transistor 212 is in the on state, transistor 212 will allow current to flow from the drain to the source, which is connected to ground. While transistor 212 is conducting in the on state, current flowing through fuse 208 will rise above the threshold current of fuse 208 (for example, 50 mA or 500 mA), thereby causing fuse 208 to fault (i.e., blow) into the opened state. The opened state of a fuse may also be referred to as the fault state or the blown state. Fuse 208 is shown in the opened state in FIG. 4, whereas fuse 208 is shown in the closed state in FIG. 2. A fuse is typically used as a protection component against too much current by opening a circuit. The present concepts involve purposefully causing fuse 208 to fault and open up so as to permanently activate lock circuit 118 so that memory 202 of IC 114 is secured against further programming.

Depending on the characteristics of fuse 208, the time required to blow fuse 208 may vary, for example, from 100 μs to 10 s. Therefore, the width w of the pulse of high level voltage, shown in FIG. 3, must be sustained long enough by input control circuit 120 to completely blow fuse 208.

Once fuse 208 is blown into the opened state, power rail line 210, which is connected to power supply 112, may no longer be connected to output line 218 of lock circuit 118. Accordingly, programmability logic 204 of IC 114 may detect a logical low voltage (e.g., 0 V) on external pin 206 (i.e., a low voltage across resistor 214) and set memory 202 in the write-protected state, which prohibits new data 402 from being written to memory 202. Thus, in some implementations of present concepts, transistor 212 can act as a pull-down switch that, when turned on, pulls the voltage on output line 218 low. Programmability logic 204 may continue (indefinitely) to lock out any further programming of memory 202 so long as the voltage level on external pin 206 remains a logical low. Accordingly, if input control circuit 120 places a high voltage at input line 216 of lock circuit 118, data writes to memory 202 of IC 114 will be prohibited.

To change data 220 stored in memory 202 (i.e., to write new data 402 to memory 202), the voltage level on external pin 206 must be brought to a logical high again. This is impossible to accomplish through software while fuse 208 in lock circuit 118 is blown. To raise the voltage level on external pin 206, fuse 208 in the opened state would need to be repaired or replaced with a replacement fuse, or external pin 206 would need to be short-circuited to power rail line 210, which would require possession of device 102 and access to the hardware components in OTP system 100. In short, the source voltage path to external pin 206 has been removed, and there is no way for the output voltage to go high again unless fuse 208 is replaced. Therefore, in essence, lock circuit 118 provides a hardware OTP option that locks data 220 in memory 202 and provides a safety feature that secures data 220 in memory 202 from undesirable changes by malicious software.

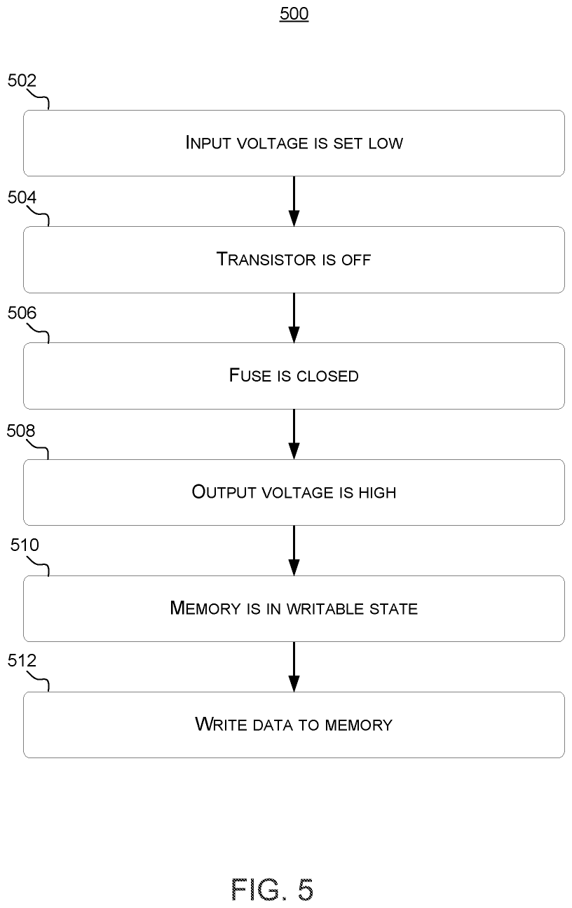

FIG. 5 shows a flow chart of an example OTP write method 500 that can implement some of the present concepts. OTP write method 500 may be performed to write to an IC by deactivating a lock circuit. In act 502, an input voltage on an input line of the lock circuit may be kept low to deactivate the lock circuit. For example, an input control circuit can output a zero voltage or a low voltage to a GPIO pin of the input control circuit that is coupled to the input line of the lock circuit. Act 502 may cause act 504, in which a transistor inside the lock circuit may be kept off. The input line of the lock circuit may be coupled to a gate terminal of the transistor. The low input voltage, which is lower than the turn-on voltage level of the transistor, on the input line of the lock circuit, and therefore on the gate terminal of the transistor, may keep the transistor in the off state. Act 504 may cause act 506, in which a fuse that is connected to a supply voltage and to a drain terminal of the transistor may be kept in the closed state. Act 506 may cause act 508, in which an output voltage on an output line of the lock circuit may be high. The output line of the lock circuit, which may be connected to the fuse, the drain terminal of the transistor, and a resistor, can have a high voltage level that is approximately the same as the supply voltage. Act 508 may cause act 510, in which memory in the IC may be placed in the writable state due to the high output voltage on the output line of the lock circuit, which may be coupled to an external pin of the IC. Programmability logic inside the IC may detect the high voltage on the external pin and set the memory in the IC to be writable. Accordingly, act 510 permits act 512 of writing data to the memory of the IC.

Optionally, the data written to the memory may be tested, validated, and/or confirmed. For example, if software code is written to the memory, the software code may be tested. If the tests fail, different software code (e.g., a corrected version of the software code) may be written over the old software code in the memory. The memory may be written to and modified multiple times so long as the lock circuit remains deactivated and the programmability logic maintains the writable state of the memory in response to detecting a logical high voltage on the external pin.

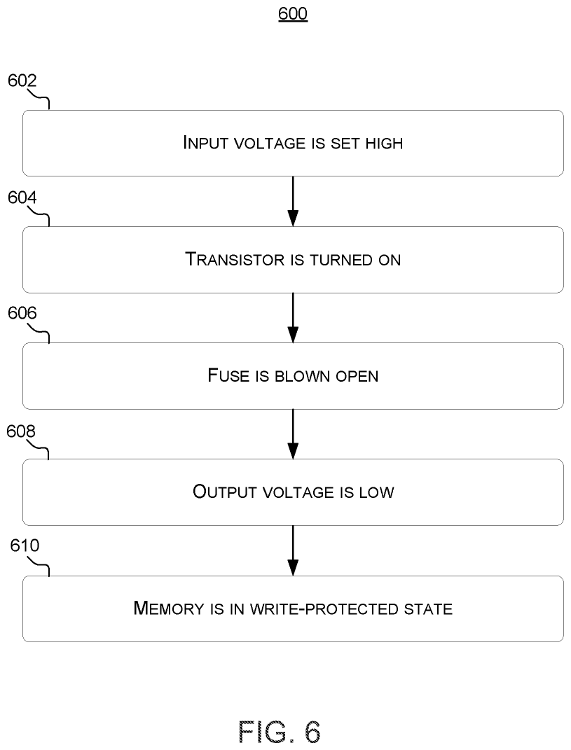

After satisfactory data is written to the memory, the data stored in the memory may be locked from future changes using, for example, a method described below in connection with FIG. 6.

FIG. 6 shows a flow chart of an OTP lock method 600 that can implement some of the present concepts. OTP lock method 600 may be performed to hardware lock the IC by activating the lock circuit. In act 602, the input control circuit may set the input voltage on the input line of the lock circuit high to activate the lock circuit. Act 602 may cause act 604, in which the transistor may be turned on. That is, the high input voltage, which is equal to or greater than the turn-on voltage level of the transistor, on the input line of the lock circuit, and thus at the gate terminal of the transistor, may transition the transistor to the on state, such that current flows from the drain to the source of the transistor. Act 604 may cause act 606, in which the fuse may blow into the opened state due to the current level flowing through the fuse rising and exceeding its threshold current level. Act 606 may cause act 608, in which the output voltage on the output line of the lock circuit may be pulled low, since the blown fuse has disconnected the output line from the supply voltage. Act 608 may cause act 610, in which the memory in the IC may be placed in the write-protected state, because the programmability logic detects the low output voltage level on the external pin. Act 610 thus may prohibit any further writing of data to the memory of the IC. OTP lock method 600 therefore can implement a hardware OTP

### Solution

Optionally, the high input voltage on the input line of the lock circuit may be brought low again by the input control circuit after the fuse has been blown to conserve power. The high input voltage on the input line of the lock circuit need not be sustained after the fuse is blown to keep the voltage level on the output line low. Therefore, only a pulse of high input voltage sufficiently long enough to blow the fuse may be necessary.

In some implementations of the present concepts, OTP write method 500 may be performed at a factory. For example, the IC may be designed such that the external pin is coupled to a write bit of the memory. Therefore, a company (e.g., a manufacturer of the IC, a purchaser of the IC, an assembler of a board that includes the IC, and/or a programmer of the IC) may perform OTP write method 500 to write data to the IC. After factory calibration of the IC is complete, OTP lock method 600 may be performed at factory to prevent future changes to the memory before a device containing the IC is shipped out. In some implementations of the present concepts, OTP write method 500 and/or OTP lock method 600 may be performed using OTP system 100 described above. The order in which the processes are described is not intended to be construed as a limitation, and any number of the described acts can be combined in any order to implement the disclosed processes or alternative implementations.

The present concepts provide a hardware solution, which is more robust than a software solution, to protect a data line. A data line (or any memory) that is protected from writes by software could possibly be undone by a malicious software manipulation that bypasses the protection. However, the disclosed hardware solution permanently blows out a fuse, thereby making it impossible to write to the data line by malicious software or a remote hacker, without hardware access.

The present concepts therefore provide a safety feature that allows companies to release electronic or computing devices that are insusceptible to changes by hackers. Rather than using conventional solutions that are integrated into silicon chips, complex, specialized, and expensive, the present concepts provide an inexpensive and simple lock circuit that uses three common, standard, off-the-shelf, board-level, discrete components to secure a data bit. Those three components take up only a small area on the board and require less voltage than traditional solutions.

Although the subject matter relating to OTP lock circuits has been described in language specific to structural features and methodological acts, it is to be understood that the subject matter defined in the appended claims is not necessarily limited to the specific features or acts described above. Rather, the specific features and acts described above are disclosed as non-limiting example forms of implementing the claims.

Various device examples are described above. Additional examples are described below. One example includes a system comprising an integrated circuit having a programmability state, the integrated circuit including an external pin, and a lock circuit that is external to the integrated circuit, the lock circuit including a transistor having an on-off state and a fuse having an open-close state that is dependent on the on-off state of the transistor and affects the programmability state of the integrated circuit, the fuse including a first terminal coupled to a supply voltage and a second terminal coupled to a drain of the transistor, a resistor, and the external pin of the integrated circuit.

Another example can include any of the above and/or below examples where an input voltage applied to a gate of the transistor controls the programmability state of the integrated circuit.

Another example can include any of the above and/or below examples where the lock circuit is a one-time programmable (OTP) circuit that permanently changes the programmability state of the integrated circuit from a writable state to a write-protected state.

Another example can include any of the above and/or below examples where applying a turn-off voltage to a gate of the transistor keeps the transistor in an off state.

Another example can include any of the above and/or below examples where the transistor in the off state keeps the fuse in a closed state.

Another example can include any of the above and/or below examples where the fuse in the closed state keeps the integrated circuit in a writable state.

Another example can include any of the above and/or below examples where applying a turn-on voltage to a gate of the transistor changes the transistor to an on state.

Another example can include any of the above and/or below examples where the transistor in the on state changes the fuse to an opened state.

Another example can include any of the above and/or below examples where the fuse in the opened state changes the integrated circuit to a write-protected state.

Another example can include any of the above and/or below examples where software cannot change the fuse in the opened state to be in a closed state and cannot change the integrated circuit in the write-protected state to be in a writable state.

Another example includes a system comprising an integrated circuit having an external pin, a fuse having a first terminal coupled to a supply voltage, the fuse being a discrete component that is external to the integrated circuit, a transistor having a drain coupled to a second terminal of the fuse, the transistor being a discrete component that is external to the integrated circuit, keeping the transistor off keeps the fuse closed and outputs a logical high voltage on the external pin to enable programming of the integrated circuit, turning the transistor on blows the fuse and outputs a logical low voltage on the external pin to disable programming of the integrated circuit, and a resistor having a first terminal coupled to the second terminal of the fuse, the drain of the transistor, and the external pin of the integrated circuit, the resistor being a discrete component that is external to the integrated circuit.

Another example can include any of the above and/or below examples where a source of the transistor and a second terminal of the resistor are coupled to ground.

Another example can include any of the above and/or below examples where the fuse, the transistor, and the resistor are soldered directly on a board and are not inside a silicon chip.

Another example can include any of the above and/or below examples where the integrated circuit includes memory that is writable when the external pin has the logical high voltage and is write-protected when the external pin has the logical low voltage.

Another example can include any of the above and/or below examples where applying a low gate voltage below a threshold voltage of the transistor maintains a current across the fuse below a threshold current of the fuse and maintains the logical high voltage on the external pin of the integrated circuit.

Another example can include any of the above and/or below examples where applying a high gate voltage above a threshold voltage of the transistor causes a current across the fuse to increase above a threshold current of the fuse, thereby blowing the fuse, and causes the logical low voltage on the external pin of the integrated circuit.

Another example can include any of the above and/or below examples where the external pin cannot remotely be made to have the logical high voltage while the fuse remains blown.

Another example can include any of the above and/or below examples where the logical high voltage is approximately the same level as the supply voltage.

Another example can include any of the above and/or below examples where the logical low voltage is approximately the same level as ground.

Another example includes a method comprising writing data to memory in an integrated circuit, the memory being programmable when a logical high voltage is detected on an external pin of the integrated circuit and being write-protected when a logical low voltage is detected on the external pin, and applying a high voltage to a gate of a discrete transistor to turn on the discrete transistor, permanently blow a discrete fuse, output the logical low voltage on the external pin of the integrated circuit, and permanently write-protect the memory, the discrete fuse having a first terminal coupled to a supply voltage and a second terminal coupled to a drain of the discrete transistor, a discrete resistor, and the external pin of the integrated circuit, the discrete fuse, the discrete transistor, and the discrete resistor being board-level components that are outside the integrated circuit.

1. A system, comprising:
an integrated circuit having a programmability state, the integrated circuit including an external pin; and
a lock circuit that is external to the integrated circuit, the lock circuit including a transistor having an on-off state and a fuse having an open-close state that is dependent on the on-off state of the transistor and affects the programmability state of the integrated circuit, the fuse including a first terminal coupled to a supply voltage and a second terminal coupled to a drain of the transistor, a resistor, and the external pin of the integrated circuit.

2. The system of claim 1, wherein an input voltage applied to a gate of the transistor controls the programmability state of the integrated circuit.

3. The system of claim 1, wherein the lock circuit is a one-time programmable (OTP) circuit that permanently changes the programmability state of the integrated circuit from a writable state to a write-protected state.

4. The system of claim 1, wherein applying a turn-off voltage to a gate of the transistor keeps the transistor in an off state.

5. The system of claim 4, wherein the transistor in the off state keeps the fuse in a closed state.

6. The system of claim 5, wherein the fuse in the closed state keeps the integrated circuit in a writable state.

7. The system of claim 1, wherein applying a turn-on voltage to a gate of the transistor changes the transistor to an on state.

8. The system of claim 7, wherein the transistor in the on state changes the fuse to an opened state.

9. The system of claim 8, wherein the fuse in the opened state changes the integrated circuit to a write-protected state.

10. The system of claim 9, wherein software cannot change the fuse in the opened state to be in a closed state and cannot change the integrated circuit in the write-protected state to be in a writable state.

11. A system, comprising:
an integrated circuit having an external pin;
a fuse having a first terminal coupled to a supply voltage, the fuse being a discrete component that is external to the integrated circuit;
a transistor having a drain coupled to a second terminal of the fuse, the transistor being a discrete component that is external to the integrated circuit, keeping the transistor off keeps the fuse closed and outputs a logical high voltage on the external pin to enable programming of the integrated circuit, turning the transistor on blows the fuse and outputs a logical low voltage on the external pin to disable programming of the integrated circuit; and
a resistor having a first terminal coupled to the second terminal of the fuse, the drain of the transistor, and the external pin of the integrated circuit, the resistor being a discrete component that is external to the integrated circuit.

12. The system of claim 11, wherein a source of the transistor and a second terminal of the resistor are coupled to ground.

13. The system of claim 11, wherein the fuse, the transistor, and the resistor are soldered directly on a board and are not inside a silicon chip.

14. The system of claim 11, wherein the integrated circuit includes memory that is writable when the external pin has the logical high voltage and is write-protected when the external pin has the logical low voltage.

15. The system of claim 11, wherein applying a low gate voltage below a threshold voltage of the transistor maintains a current across the fuse below a threshold current of the fuse and maintains the logical high voltage on the external pin of the integrated circuit.

16. The system of claim 11, wherein applying a high gate voltage above a threshold voltage of the transistor causes a current across the fuse to increase above a threshold current of the fuse, thereby blowing the fuse, and causes the logical low voltage on the external pin of the integrated circuit.

17. The system of claim 11, wherein the external pin cannot remotely be made to have the logical high voltage while the fuse remains blown.

18. The system of claim 11, wherein the logical high voltage is approximately the same level as the supply voltage.

19. The system of claim 11, wherein the logical low voltage is approximately the same level as ground.

20. A method, comprising:
writing data to memory in an integrated circuit, the memory being programmable when a logical high voltage is detected on an external pin of the integrated circuit and being write-protected when a logical low voltage is detected on the external pin; and
applying a high voltage to a gate of a discrete transistor to turn on the discrete transistor, permanently blow a discrete fuse, output the logical low voltage on the external pin of the integrated circuit, and permanently write-protect the memory, the discrete fuse having a first terminal coupled to a supply voltage and a second terminal coupled to a drain of the discrete transistor, a discrete resistor, and the external pin of the integrated circuit, the discrete fuse, the discrete transistor, and the discrete resistor being board-level components that are outside the integrated circuit.
